(19) United States
(12) Patent Application Publication
(10) Pub. No.: US 2026/0333851 A1
(43) Pub. Date: Oct. 22, 2026

(54) SELF-ALIGNED DIRECT BACKSIDE CONTACT UNDER-STRAP

(71) Applicant: INTERNATIONAL BUSINESS MACHINES CORPORATION, ARMONK, NY (US)

(72) Inventors: Reinaldo Vega, Mahopac, NY (US); Minhaz Abedin, Delmar, NY (US); Mahender Kumar, Clifton Park, NY (US); Xiaoming Yang, Clifton Park, NY (US); Ravikumar Ramachandran, Pleasantville, NY (US)

(21) Appl. No.: 19/186,555

(22) Filed: Apr. 22, 2025

(51) Int. Cl. H10D 84/83; H01L 21/768; H10D 30/00; H10D 30/01; H10D 30/43; H10D 62/10; H10D 62/13; H10D 64/23; H10D 84/01

(52) U.S. Cl. CPC H10D 84/832; H10D 30/014; H10D 30/019; H10D 30/43; H10D 30/502; H10D 62/121; H10D 62/151; H10D 64/256; H10D 84/0149; H10D 84/8312; H10W 20/069

(57) ABSTRACT

A semiconductor device includes a gate region, an active region surrounded by the gate region, at least one source/drain region, and a backside contact below the at least one source/drain region and having a first portion with a first height. A length of the first portion along the active region is smaller than a length of the active region.

### BACKGROUND

### Technical Field

The present disclosure generally relates to semiconductors, and more particularly, to semiconductor devices with self-aligned direct backside contract under-strap structure, and methods of creation thereof.

### Description of Related Art

The continuous miniaturization of transistors and their increasing density on chips epitomize the semiconductor industry's innovation, largely adhering to Moore's Law. This trend has led to transistors shrinking to nanometer scales, allowing millions and even billions to fit on a single chip, significantly enhancing computational power and energy efficiency. The evolution towards system-on-chip architectures integrates various functionalities, including processing and sensing, on one chip.

### SUMMARY

According to an embodiment, a semiconductor device includes a gate region, an active region surrounded by the gate region, at least one source/drain region, a backside contact below the at least one source/drain region and having a first portion having a first height. A length of the first portion is smaller than a length of the active region.

In some embodiments, the semiconductor device includes a second portion connected to the first portion and having a second height. A length of the second portion is greater than a length of the first portion.

In one embodiment, the second height is greater than the first height.

In one embodiment, the semiconductor device includes an offset spacer between two opposite edges of the active region and outer edges of the backside contact along a horizontal length of the semiconductor device.

In some embodiments, the offset spacer is located on sidewalls of the backside contact and between the backside contact and a substrate, along a length of the semiconductor device.

In some embodiments, parts of the first portion extend vertically into the active region.

In some embodiments, the semiconductor device includes a frontside contact electrically connected to a frontside of the semiconductor device.

In some embodiments, the first portion and the second portion include the same material.

In some embodiments, the first portion and the second portion include different materials.

According to an embodiment, a method of fabricating a semiconductor device includes forming an active region, forming a gate region surrounded by the active region, forming at least one source/drain region, and forming a backside contact below the at least one source/drain region and having a first portion with a first height. A length of the first portion is smaller than a length of the active region

In one embodiment, the method includes forming a second portion having a second height and connected to the first portion. A length of the second portion is greater than a length of the first portion.

In one embodiment, the second height is greater than the first height.

In some embodiments, the method includes forming an offset spacer which lines an inner periphery of an opening of the backside contact.

In some embodiments, the method includes vertically extending parts of the first portion into the active region.

In one embodiment, the method includes forming a frontside contact over the active region, and connecting the active region to a frontside of the semiconductor device via frontside contact.

In one embodiment, the first portion and the second portion include a same material.

In one embodiment, the first portion and the second portion include different materials.

According to an embodiment, a semiconductor device includes a source/drain region, a backside contact below the source/drain region, where a width of the backside contact is smaller than a width of an active region of the semiconductor device, and an offset spacer between two opposite edges of the source/drain region and outer edges of the backside contact along a length of the semiconductor device.

In some embodiments, the offset spacer lines an inner periphery of at least a vertical portion of the backside contact, and portions of the backside contact extend vertically into the source/drain region.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1A illustrates a top view of a semiconductor device, according to some embodiments.

FIGS. 1B-1E illustrate the semiconductor device shown in FIG. 1A from various cross-sections.

FIGS. 2A-2B, illustrate a semiconductor device, after the formation of the initial structure, according to some embodiments.

FIGS. 3A-3B illustrate a semiconductor device after the thinning of the backside substrate, consistent with an illustrative embodiment.

FIGS. 4A-4B illustrate a semiconductor device after the formation of the backside diffusion break, consistent with an illustrative embodiment.

FIGS. 5A-5B illustrate a semiconductor device after the etching of the first backside contact, consistent with an illustrative embodiment.

FIGS. 6A-6B illustrate a semiconductor device after the formation of the spacer, according to an embodiment.

FIGS. 7A-7B illustrate a semiconductor device after the etching of second the backside contact, consistent with an illustrative embodiment.

FIGS. 8A-8B illustrate a semiconductor device after the formation of the backside contacts, consistent with an illustrative embodiment.

FIG. 9 illustrates a top view of the semiconductor device after the formation of the backside contact, consistent with an illustrative embodiment.

FIGS. 10A-10B illustrate a semiconductor device after the removal of the spacer, consistent with an illustrative embodiment.

FIGS. 11A-11B illustrate a semiconductor device after the formation of the backside contact, consistent with an illustrative embodiment.

FIGS. 12A-12B illustrate a semiconductor device, after the formation of the initial structure, consistent with an illustrative embodiment.

FIGS. 13A-13B illustrate a semiconductor device after the thinning of the backside substrate, consistent with an illustrative embodiment.

FIGS. 14A-14B illustrate a semiconductor device after the formation of the backside contact, consistent with an illustrative embodiment.

FIGS. 15A-15B illustrate a semiconductor device after the etching of the first backside contact, consistent with an illustrative embodiment.

FIGS. 16A-16B illustrate a semiconductor device after the formation of the spacer, according to an embodiment.

FIGS. 17A-17B illustrate a semiconductor device after the etching of the second backside contact, consistent with an illustrative embodiment.

FIGS. 18A-18B illustrate a semiconductor device after the formation of the backside contacts, consistent with an illustrative embodiment.

FIGS. 19A-19B illustrate a semiconductor device after polishing the semiconductor device, consistent with an illustrative embodiment.

FIGS. 20A-20B illustrate a semiconductor device after the removal of the spacer, consistent with an illustrative embodiment.

FIGS. 21A-21B illustrate a semiconductor device after the formation of the backside contact, consistent with an illustrative embodiment.

FIG. 22 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter can be combined with elements of different embodiments.

According to an embodiment, a semiconductor device includes a gate region, an active region surrounded by the gate region, at least one source/drain region, a backside contact below the at least one source/drain region and having a first portion having a first height, and a second portion. A length of the first portion is smaller than a length of the active region. The first backside contact is under-strapped which reduces the risk of an electrical short between the backside contact and the gate electrode.

In some embodiments, the semiconductor device includes a second portion connected to the first portion and having a second height. A length of the second portion is greater than a length of the first portion, which facilitates easier connectivity to backside metallization.

In one embodiment, the second height is less than the first height. The under-strapped backside contact has a smaller height than the other backside contacts.

In one embodiment, the semiconductor device includes an offset spacer between two opposite edges of the active region and outer edges of the backside contact along a length of the semiconductor device. The spacer enables self-aligned under-strapping of the backside contact.

In one embodiment, parts of the first portion extend vertically into the active region. Thus, the electrical connection between the active region and the backside contact increases from a 2D into 3D.

In one embodiment, the semiconductor device includes a frontside contact over the active region and connecting the active region to a frontside of the semiconductor device. Thus, the semiconductor device can be electrically connected to other chips on both frontside and backside.

In one embodiment, the first portion and the second portion are made of a same material. This can facilitate the fabrication process.

In one embodiment, the first portion and the second portion are made of different materials. This enables adjusting properties of the semiconductor device.

According to an embodiment, a method of fabricating a semiconductor device includes forming an active region, forming a gate region surrounded by the active region, forming at least one source/drain region, and forming a backside contact below the at least one source/drain region and having a first portion with a first height. A length of the first portion is smaller than a length of the active region. The first backside contact is under-strapped which reduces the risk of an electrical short between the backside contact and the gate electrode.

In one embodiment, the method includes forming a second portion having a second height and connected to the first portion. A length of the second portion is greater than a length of the first portion, which facilitates easier connectivity to backside metallization.

In one embodiment, the second height is less than the first height. The under-strapped backside contact has a smaller height than the other backside contacts.

In one embodiment, the method includes forming an offset spacer between two opposite edges of the active region and outer edges of the backside contact. The spacer enables self-aligned under-strapping of the backside contact.

In one embodiment, the method includes intruding parts of the first portion into the active region. Thus, the electrical connection between the active region and the backside contact increases from a 2D into 3D.

In one embodiment, the method includes forming a frontside contact over the active region, and connecting the active region to a frontside of the semiconductor device via frontside contact. Thus, the semiconductor device can be electrically connected to other chips on both frontside and backside.

In one embodiment, the first portion and the second portion are made of a same material. This can facilitate the fabrication process.

In one embodiment, the first portion and the second portion are made of different materials. This enables adjusting properties of the semiconductor device.

According to an embodiment, a semiconductor device includes a source/drain region, a backside contact below the source/drain region, where a width of the backside contact is smaller than a width of an active region of the semiconductor device, and an offset spacer between two opposite edges of the source/drain region and outer edges of the backside contact along a length of the semiconductor device. The first backside contact is under-strapped which reduces the risk of an electrical short between the backside contact and the gate electrode.

In one embodiment, the semiconductor device includes an insulation layer on sidewalls of the backside contact and between the offset spacer and the source/drain region. Portions of the backside contact extend vertically into the source/drain region. Thus, the electrical connection between the active region and the backside contact increases from a 2D into 3D.

In bulk nanosheet semiconductor devices, the gate region (PC) extends around the edges of the active regions (RX). This extension results in what are referred to as PC “fangs.” These protrusions are a byproduct of fabrication and introduce a complication during the formation of the backside contacts. The proximity of these PC fangs to the backside contacts can cause electrical shorts, particularly when the backside contacts are fully strapped, meaning it matches or exceeds the width of the RX. This risk necessitates limiting the depth to which reactive ion etching (RIE) can be applied during backside contact formation to avoid short circuits.

To address these issues, under-strapping the backside contact is a feasible approach. By designing the backside contact to be narrower than the RX, the likelihood of shorts occurring between the PC fangs and the backside contact in the transverse direction of the RX is reduced. However, this brings about another challenge: it becomes difficult to accurately pattern the backside contact when the RX is narrow, due to the reduced width that must be precisely aligned and etched.

Disclosed is a semiconductor device with an under-strapped backside contact structure that is adapted to the variable widths of RX. The disclosed structure improves the scalability of the semiconductor device fabrication process by ensuring that the backside contact can be effectively and reliably patterned, even in scenarios where the RX is narrow. This leads to enhanced device performance and reliability, addressing both the risk of shorts and the challenges of backside contact patterning in various RX dimensions.

Accordingly, the teachings herein provide methods and systems of a semiconductor device with under-strapped backside contact structures. The techniques described herein may be implemented in a number of ways. Example implementations are provided below with reference to the following figures.

### Example Semiconductor Device with Under-Strapped Backside Contact Structure

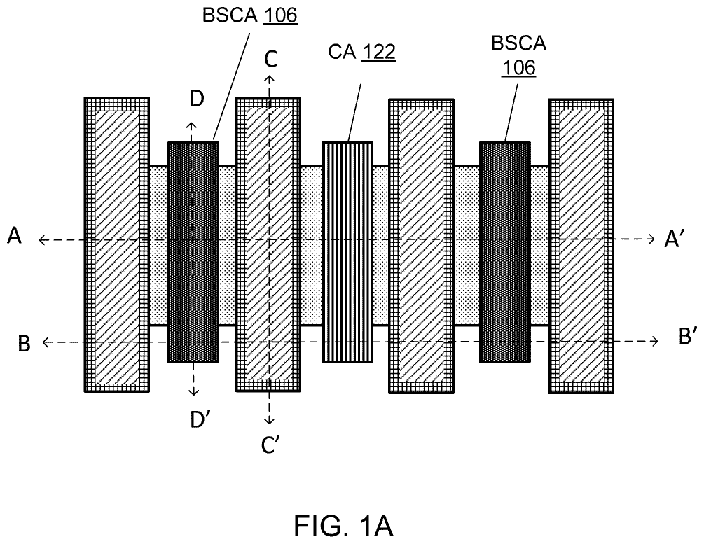

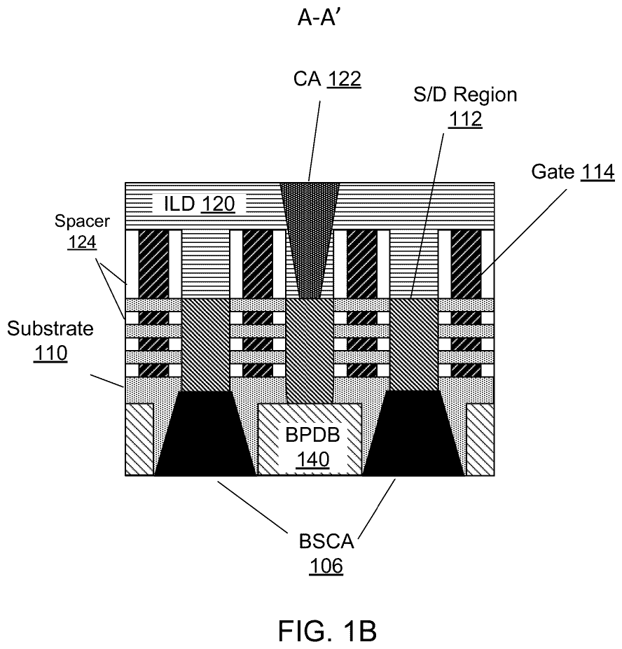

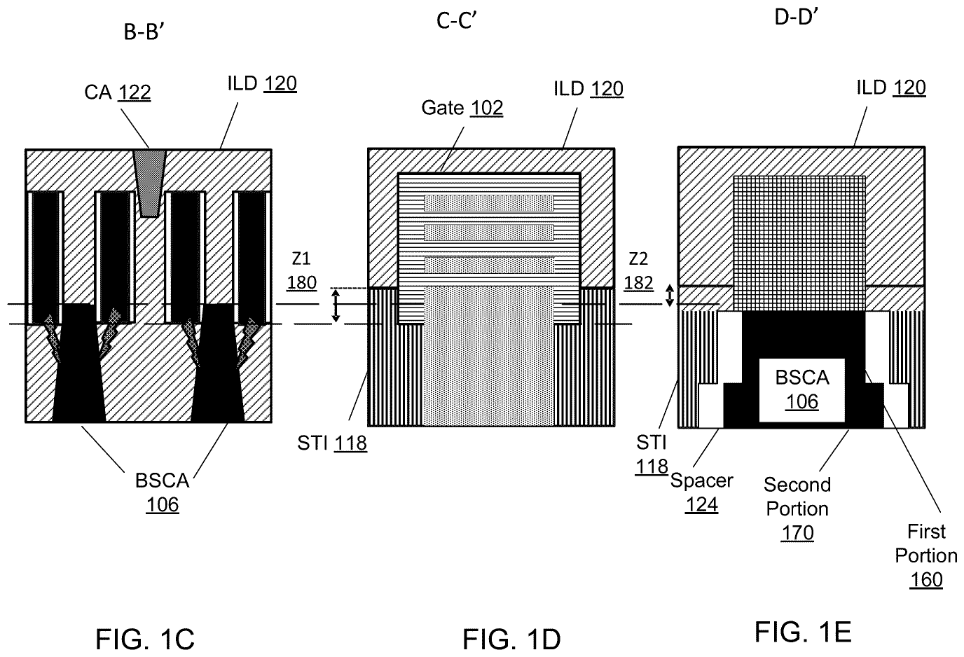

Reference now is made to FIGS. 1A-1E, which are simplified top view and cross-section views of the semiconductor device. It should be noted that FIGS. 1A-1E depict the shorting issue which motivates the present disclosure. FIG. 1A illustrates a top view of a semiconductor device, according to some embodiments. FIGS. 1B-1E illustrate the semiconductor device shown in FIG. 1A from various cross-sections. In some embodiments, the semiconductor device includes a gate region 114 and an interlayer dielectric, ILD 120. The ILD 120 can be situated at the uppermost portion of the device structure. The gate region 114 functions as a control mechanism for modulating the electrical properties of the active region positioned directly beneath it. By applying different voltage levels to the gate region 114, the gate region 114 alters the conductivity state of the active region.

In semiconductor device fabrication, the design and alignment of various structural elements are salient for ensuring functionality and preventing failures. Specifically, in some embodiments, the gate region of the semiconductor device wraps around the active region and extends into the STI to a specified depth, denoted as Z1 180. Such an architectural feature, e.g., Z1 180, can cause short between the backside contact and gate regions.

During the manufacturing process, the backside of the semiconductor wafer is etched, aiming to create openings that reach a certain depth into the substrate. This depth Z2 182 can represent the distance remaining to the surface of the substrate after the etching process has been completed. The precision in etching to achieve the desired Z2 182 is important as it ensures that the structural integrity and functional isolation of different regions within the semiconductor are maintained. Furthermore, the portions that overlap between BSCA 106 and the gate region 102 can create additional risk of short.

Visualizing this scenario in a cross-sectional view along the B-B′ line can provide a clearer understanding of the risks involved. If Z2 182 is equal to or less than Z1 180, the backside etching can remove more material than intended, exposing the gate electrode to the backside contacts. This proximity can create a direct electrical connection between the gate and other regions, contrary to the design intentions which seek to maintain strict separation for proper device operation.

In some embodiments, the active region serves as the main pathway for electronic charge carriers, either electrons or holes, depending on the type of semiconductor material used. The functionality of the active region is important for the device's performance, influencing its speed, efficiency, and power handling capabilities. The design and material characteristics of the active region can determine its effectiveness in conducting charge carriers between the source and drain regions, thereby impacting the overall device efficiency. The active region can be positioned between the gate structure and the substrate within the semiconductor device, and include the conduction channel that forms when the device is activated by applying voltage. The area can be doped differently from other parts of the semiconductor to facilitate or control the movement of charge carriers such as electrons or holes.

By modulating the conductivity of the active region through varying voltages applied at the gate terminal, the device can effectively switch between on and off states or amplify signals. In field-effect transistors, including MOSFETs, the active region includes the channel that forms under the gate oxide when a gate voltage surpasses a certain threshold. The characteristics of this channel—such as its length, width, and doping—significantly influence the device's operational parameters like threshold voltage, on-resistance, and transconductance. The active region is also flanked by source and drain regions in a transistor. These areas are heavily doped to facilitate the injection and collection of carriers from the channel. Different materials are used for the active region depending on the specific requirements of the semiconductor device. Silicon can be used, but materials such as gallium arsenide (GaAs), silicon carbide (SiC), and materials such as graphene and transition metal dichalcogenides are selected for applications requiring higher speed or power handling capabilities.

In some embodiments, the BSCA 106 is positioned below the source/drain region to enhance electrical properties and connectivity. The BSCA 106 can be structured into two portions, each contributing uniquely to the semiconductor device's overall effectiveness. The first portion 160 of the backside contact has a first height. This dimension can determine the vertical extent of the BSCA 106 relative to the substrate and influence aspects such as electrical resistance and the ability to dissipate heat.

Connected to the first portion 160 is the second portion 170, which exhibits a second height that can differ from the first height. Notably, the width of the second portion 170 can be greater than or equal to the width of the active region to ensure that the second portion 170 can adequately support the active region above it, providing a stable and robust platform for the active components of the device. In some embodiments, the length of the backside contact 106 can be smaller than the length of the active region itself. Here, the length of the active region and the length of the backside contact (or the first portion 160 or the second portion 170) are defined as being measured along a width direction of the gate region 114. In other words, they are measured in a left/right direction illustrated in FIG. 1D and in FIG. 1E, respectively. The heights of the first portion 160 and the second portion 170 of the backside contact 106 are measured in a vertical direction as illustrated in FIG. 1E. In more details, the backside contact 106 does not extend horizontally across the entire length of the active region, allowing for differential scaling of functional areas within the semiconductor device.

The configuration of the backside contact, with its two portions having distinct heights and the second portion's width aligning with or exceeding that of the active region, underscores the semiconductor device's advanced design. The narrowing of the first portion serves to reduce the risk of an electrical short between the backside contact and the gate electrode. This configuration helps to increase device yield. Further, the second height being less than the first height allows for a stepped arrangement beneficial for optimizing both yield and connectivity.

In some embodiments, an offset spacer, e.g., spacer 124, is positioned between the opposing edges of the active region and the outer edges of the first portion. This spacer 124 facilitates self-alignment of the BSCA 106 under-strapping. By increasing or decreasing the thickness of spacer 124, the amount by which BSCA 106 under-straps the active region can be either increased or decreased, respectively.

In some embodiments, parts of the first portion extend vertically into the active region. This design can be used to increase the overall contact area between the BSCA 106 and the source/drain region 112.

In some embodiments, a frontside contact, CA 122, is placed above the active region, facilitating electrical connection to the frontside of the semiconductor device. This contact can interface the semiconductor device with external circuit elements, and provide a point of electrical access that complements the connections provided by the backside contacts.

In some embodiments, the first portion and the second portion are constructed from the same material, which simplifies manufacturing processes and ensures uniform thermal and electrical behavior across these components. Alternatively, these portions can be made from different materials, chosen specifically to optimize their respective functions within the device. For instance, a material with higher thermal conductivity can be used for the second portion to enhance heat dissipation, while a material with optimal electrical properties can be selected for the first portion to improve its conductive efficiency.

### Example Fabrication of a Semiconductor Device with Under-Strapped Backside Contact Structure

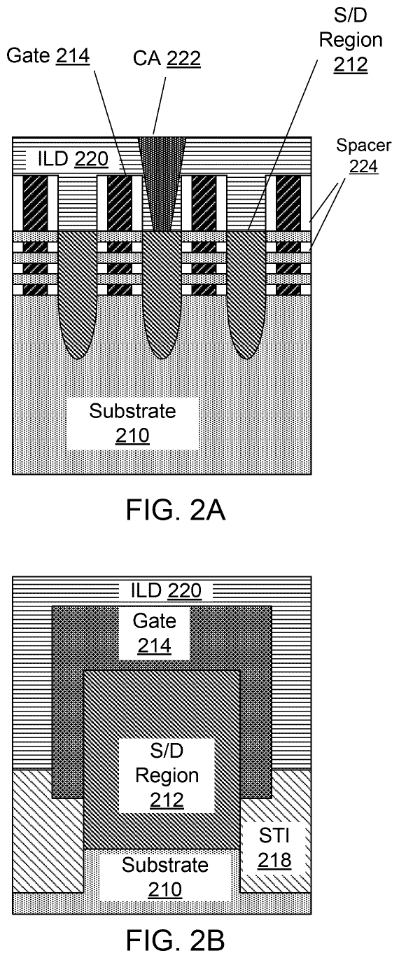

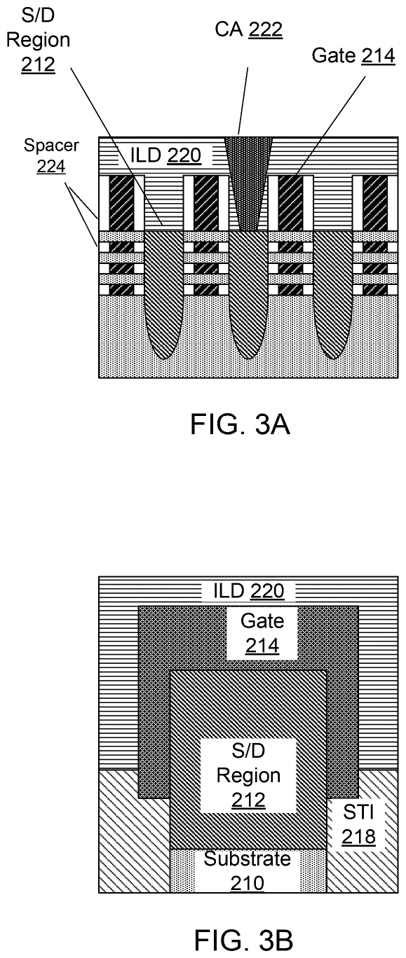

With the foregoing description of an example semiconductor device, it may be helpful to discuss an example process of manufacturing the same. To that end, FIGS. 2-3 illustrate various acts in the manufacture of a semiconductor device, consistent with illustrative embodiments. Figures denoted by A depict the cross-gate section, e.g., middle of the active region, and figures denoted by B depict the cross-source/drain region section of the semiconductor device.

Reference now is made to FIGS. 2A-2B, which are simplified cross-section views of a semiconductor device, after the formation of the initial structure, consistent with an illustrative embodiment. The semiconductor can include a substrate 210, a source/drain region 212, a gate region 214, shallow trench isolation, STI 218, an interlayer dielectric layer, ILD 220, frontside contact, CA 222, and sidewall spacers, e.g., spacers 224.

The source/drain region 212 in a semiconductor device interfaces directly with the channel region under the gate. These regions are heavily doped to facilitate the injection and collection of charge carriers (electrons or holes) into the channel when the device is operational. Their conductivity is important for the efficient performance of transistors, enabling current to flow through the device when the gate is activated. The source/drain region 212 can be tailored depending on the device type and requirements, including their doping concentration and depth to optimize device performance.

The gate region 214 controls the flow of carriers in the channel of a semiconductor device, such as a MOSFET. Positioned directly above the channel and separated by a thin insulating layer, e.g., the offset spacer which can be made of silicon dioxide or high-k material, the gate region 214 acts as the switch for the transistor. Applying voltage to the gate creates an electric field that controls the conductivity of the channel, allowing the gate region to effectively turn the device on or off. The design and material of the gate are critical for determining the transistor's threshold voltage, leakage current, and overall speed.

STI 218 is used to electrically isolate transistors from one another within a semiconductor wafer. By etching shallow trenches in the silicon substrate and filling them with an insulating material (such as silicon dioxide), STI 218 prevents electrical leakage and crosstalk between adjacent devices. This isolation is essential for reducing interference and improving the performance and scalability of integrated circuits. The depth and width of the trenches are designed to meet the specific isolation requirements of the device architecture.

ILD 220 is a layer of insulating material used in semiconductor devices to separate different layers of metal interconnects. This insulation prevents electrical shorts between metal layers and provides mechanical support for the structure. Common materials used for ILD 220 include silicon dioxide, fluorinated silica glass, and low-k dielectrics, which are chosen based on their insulating properties and compatibility with the overall device fabrication process. The ILD plays a role in maintaining the integrity and performance of multi-layered semiconductor devices.

CA 222 provides the electrical interface between the semiconductor device's internal structures and the external circuit elements. This contact is typically made from a metal or metal silicide and is designed to form ohmic contacts with the source/drain regions. Frontside contacts deliver signals into and out of the semiconductor device, and their design and placement are key to achieving low resistance and high-performance connectivity.

The sidewall spacer, e.g., the spacer 224, is a structural element formed on the sidewalls of the gate region and between the nanosheet channels, separating the S/D region 212 from the gate region 214. Made from an insulating material such as silicon nitride or oxide, these spacers serve to prevent electrical shorting between the gate region 214 and S/D region 212 and furthermore reduce parasitic capacitance between these two regions. The sidewall spacer 224 can help in controlling the short-channel effects by physically separating the gate from the heavily doped source/drain extensions. This separation helps to reduce gate leakage and improve the electrical performance of the device.

In the illustrative example depicted in FIGS. 2A-2B, the semiconductor device is depicted as being on silicon as the substrate 210, while it will be understood that other types as the substrate 210 can be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the substrate 210 can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

FIGS. 3A-3B illustrate a semiconductor device after the thinning of the backside substrate, consistent with an illustrative embodiment. In some embodiments, the backside substrate, e.g., the substrate 210, is thinned.

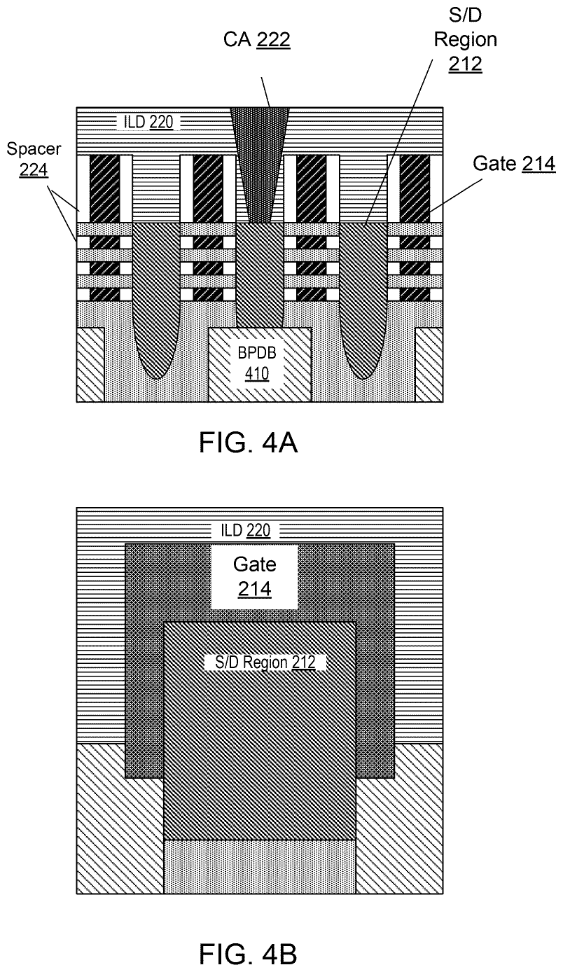

FIGS. 4A-4B illustrate a semiconductor device after the formation of the backside partial diffusion break, consistent with an illustrative embodiment. The backside partial diffusion break, BPDB 410, is formed on the backside of the semiconductor device.

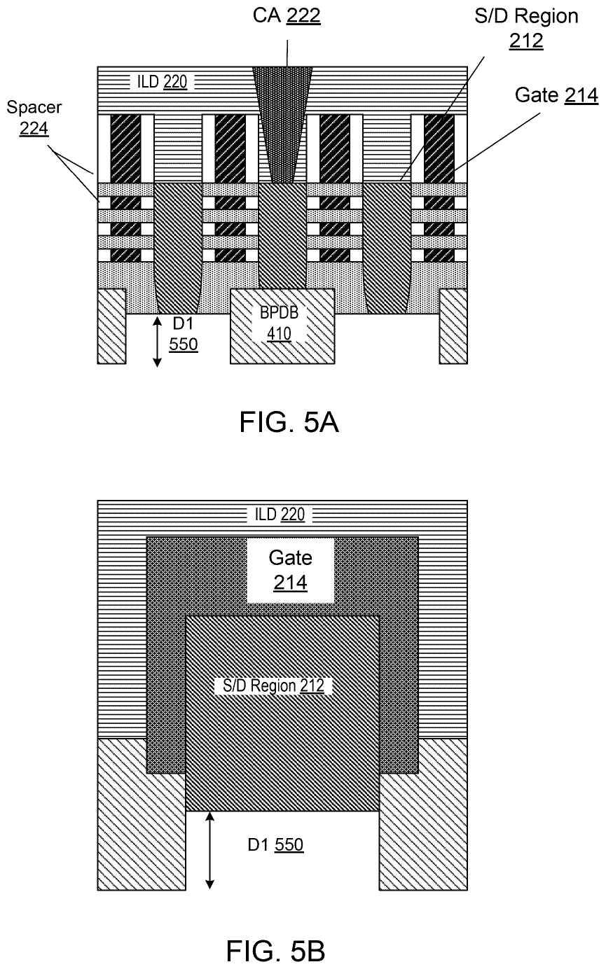

FIGS. 5A-5B illustrate a semiconductor device after the etching of the first backside contact opening, consistent with an illustrative embodiment. In some embodiments, portions of the substrate between the BPDB 410 and the STI 218 are removed. To that end, a reactive ion etching, RIE, can be used. RIE combines physical and chemical processes to create precise and highly anisotropic patterns on a substrate, typically silicon or other semiconductor materials. In Reactive Ion Etching, a mixture of gases is introduced into a low-pressure chamber containing the substrate. An electric field is then applied to ionize the gas, creating plasma-a hot, ionized state of the gas consisting of positive ions, electrons, and reactive neutral species. The substrate is placed on a powered electrode, which attracts these ions. The ions strike the substrate with directional energy due to the electric field, physically sputtering away the material from the surface. Simultaneously, the reactive species in the plasma chemically react with the material on the substrate. These reactions often form volatile byproducts, which are then evacuated from the chamber. The synergy between the physical sputtering caused by ion bombardment and the chemical reactions induced by reactive species enables precise control over the etch profile and rate, which is essential for achieving high-resolution patterns. The depth of the etching can be d1 550.

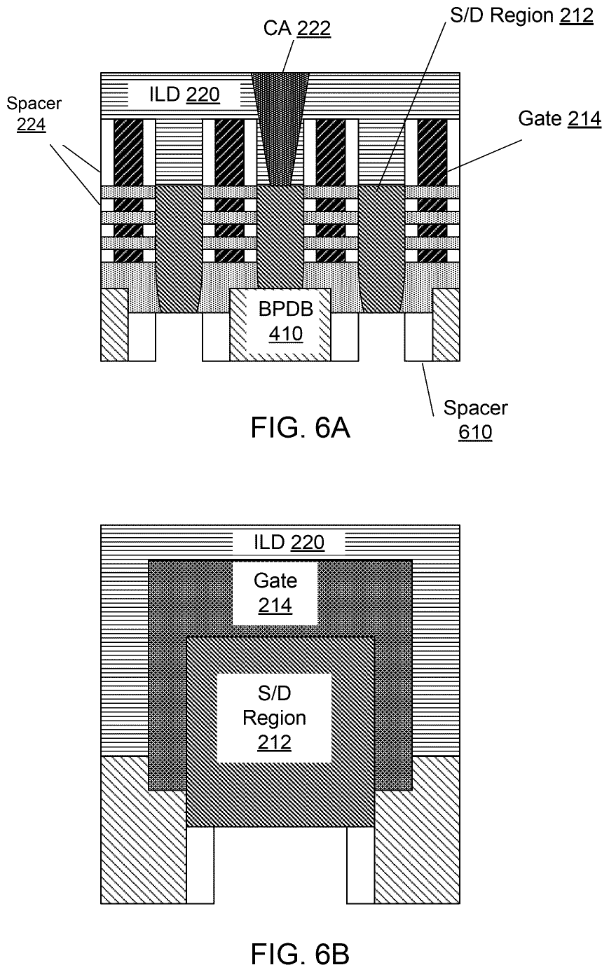

FIGS. 6A-6B illustrate a semiconductor device after the formation of the spacer, according to an embodiment. In some embodiments, a spacer 610 is formed over the substrate on the backside of the semiconductor device.

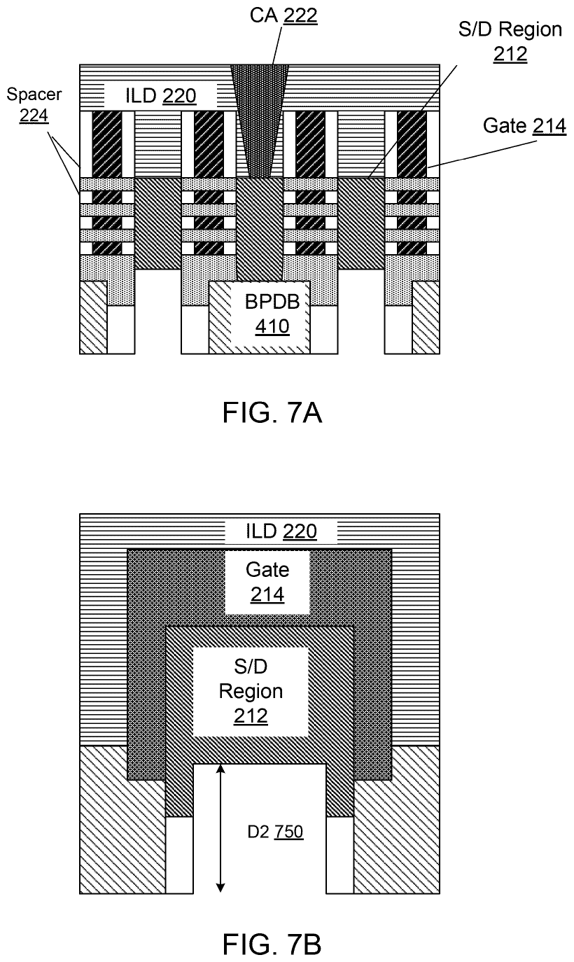

FIGS. 7A-7B illustrate a semiconductor device after the etching of the second portion of the backside contact opening, consistent with an illustrative embodiment. In some embodiments, the portions of the source/drain regions 212 that are exposed, are removed, such that a cavity with the height d2 750 is formed.

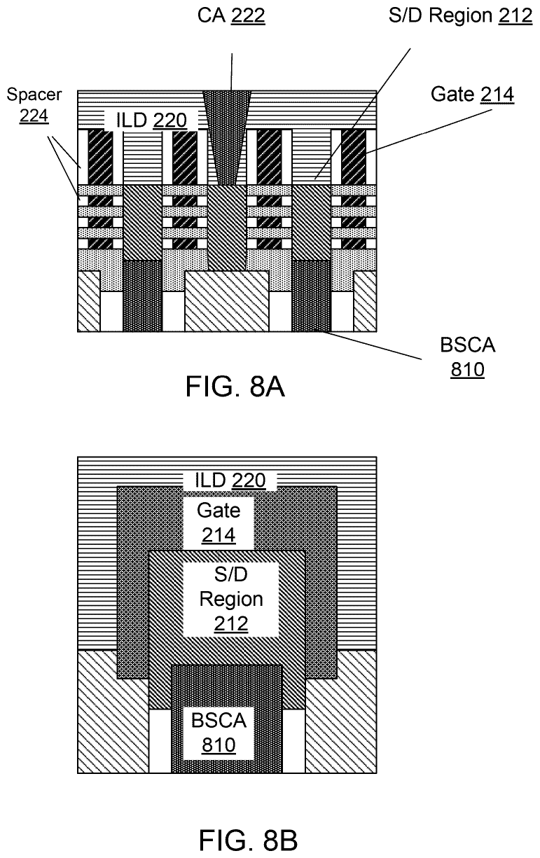

FIGS. 8A-8B illustrate a semiconductor device after the formation of the backside contact, consistent with an illustrative embodiment. In some embodiments, the cavity is filled with a suitable material to form the backside contacts, BSCA 810.

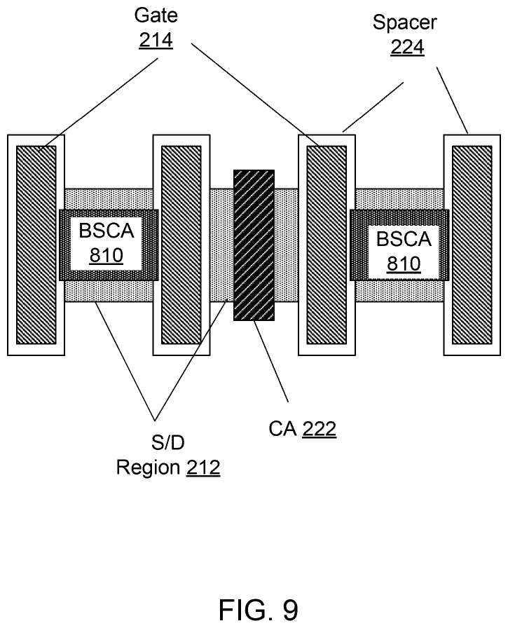

FIG. 9 illustrates a top view of the semiconductor device after the formation of the backside contact, consistent with an illustrative embodiment.

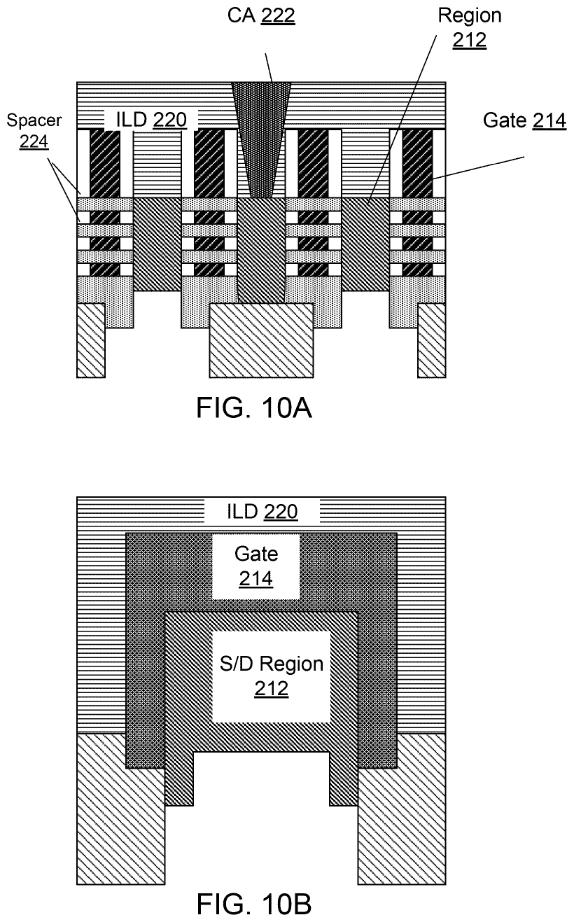

FIGS. 10A-10B illustrate a semiconductor device after the removal of the spacer, consistent with an illustrative embodiment. In some embodiments, after the second backside contact is etched, the spacer is removed selectively from the backside of the semiconductor device.

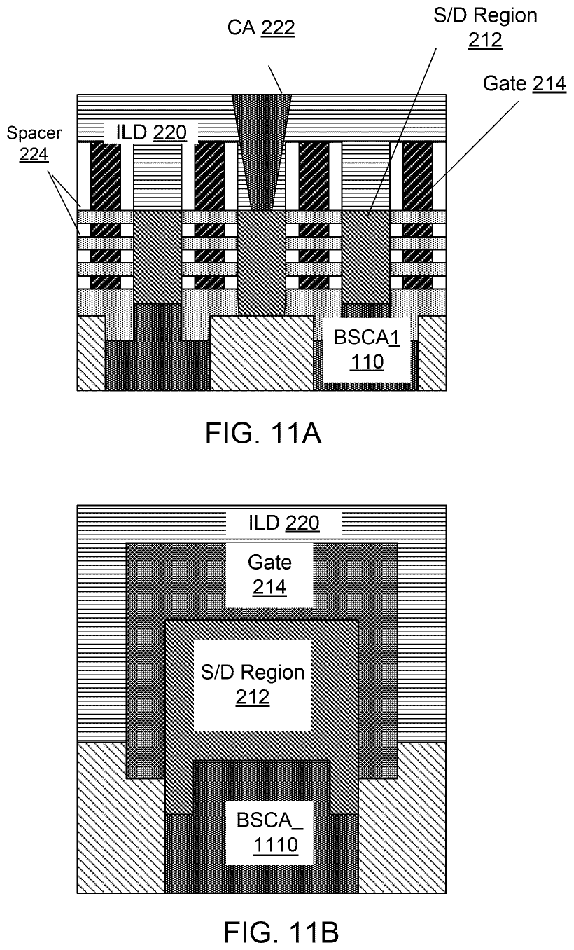

FIGS. 11A-11B illustrate a semiconductor device after the formation of the backside contact, consistent with an illustrative embodiment. In some embodiments, the cavity and portions of the substrate that are exposed after the removal of the spacer are filled with a suitable material to form the second backside contact, BSCA 1110.

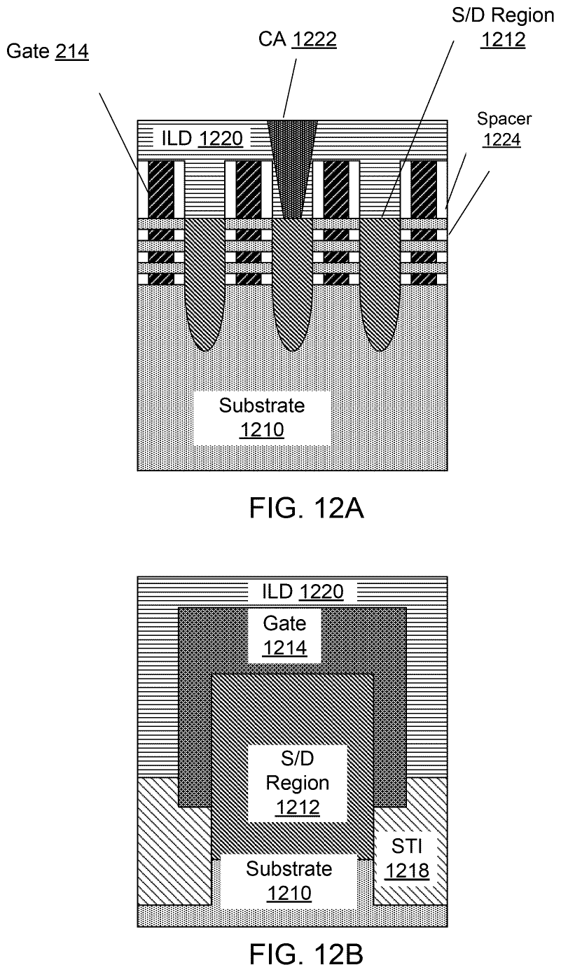

FIGS. 12-19 illustrate various acts in the manufacture of a semiconductor device, consistent with illustrative embodiments.

Reference now is made to FIGS. 12A-12B, which are simplified cross-section views of a semiconductor device, after the formation of the initial structure, consistent with an illustrative embodiment. The semiconductor can include a substrate 1210, a source/drain region 1212, a gate region 1214, shallow trench isolation, STI 1218, an interlayer dielectric layer, ILD 1220, frontside contact, CA 1222, and spacer 1224.

The source/drain region 1212 in a semiconductor device interfaces directly with the channel region under the gate. These regions are heavily doped to facilitate the injection and collection of charge carriers (electrons or holes) into the channel when the device is operational. Their conductivity is important for the efficient performance of transistors, enabling current to flow through the device when the gate is activated. The source/drain region 1212 can be tailored depending on the device type and requirements, including their doping concentration and depth to optimize device performance.

The gate region 1214 controls the flow of carriers in the channel of a semiconductor device, such as a MOSFET. Positioned directly above the channel and separated by a thin insulating layer, e.g., the offset spacer, the gate region 1214 acts as the switch for the transistor. Applying voltage to the gate creates an electric field that controls the conductivity of the channel, allowing the gate region to effectively turn the device on or off. The design and material of the gate are critical for determining the transistor's threshold voltage, leakage current, and overall speed.

STI 1218 is used to electrically isolate transistors from one another within a semiconductor wafer. By etching shallow trenches in the silicon substrate and filling them with an insulating material (such as silicon dioxide), STI 1218 prevents electrical leakage and crosstalk between adjacent devices. This isolation is essential for reducing interference and improving the performance and scalability of integrated circuits. The depth and width of the trenches are designed to meet the specific isolation requirements of the device architecture.

ILD 1220 is a layer of insulating material used in semiconductor devices to separate different layers of metal interconnects. This insulation prevents electrical shorts between metal layers and provides mechanical support for the structure. Common materials used for ILD 1220 include silicon dioxide, fluorinated silica glass, and low-k dielectrics, which are chosen based on their insulating properties and compatibility with the overall device fabrication process. The ILD plays a role in maintaining the integrity and performance of multi-layered semiconductor devices.

CA 1222 provides the electrical interface between the semiconductor device's internal structures and the external circuit elements. This contact is typically made from a metal or metal silicide and is designed to form ohmic contacts with the source/drain regions. Frontside contacts deliver signals into and out of the semiconductor device, and their design and placement are key to achieving low resistance and high-performance connectivity.

The sidewall spacer, e.g., spacer 1224, is a structural element formed on the sidewalls of the gate region and between the nanosheet channels, separating the S/D region 212 from the gate region 214. Made from an insulating material such as silicon nitride or oxide, these spacers serve to prevent electrical shorting between the gate region 1214 and S/D region 1212 and furthermore reduce parasitic capacitance between these two regions. The spacer 1224 can help in controlling the short-channel effects by physically separating the gate from the heavily doped source/drain extensions. This separation helps to reduce gate leakage and improve the electrical performance of the device.

In the illustrative example depicted in FIGS. 12A-12B, the semiconductor device is depicted as being on silicon as the substrate 1210, while it will be understood that other types as the substrate 1210 can be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the substrate 1210 can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

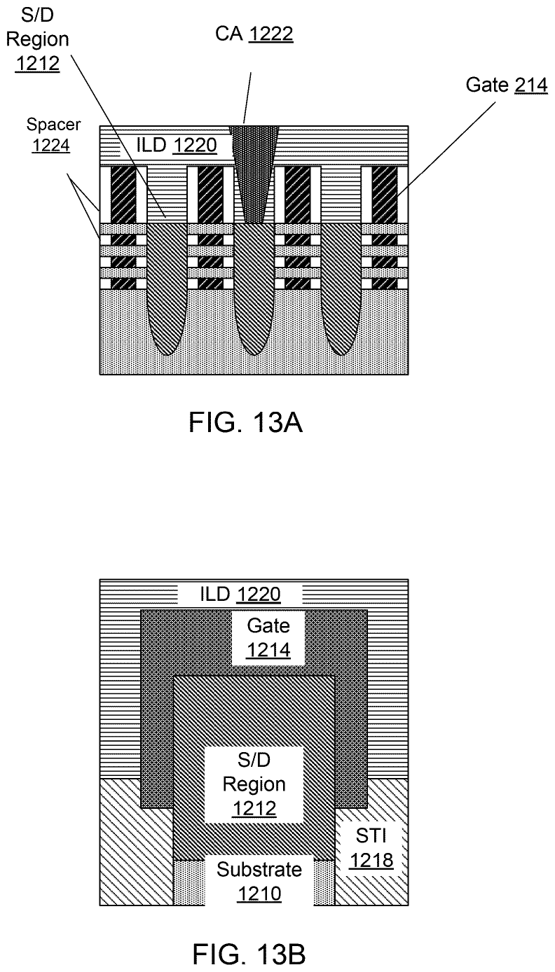

FIGS. 13A-13B, illustrate a semiconductor device after the thinning of the backside substrate, consistent with an illustrative embodiment. In some embodiments, the backside substrate, e.g., the substrate 1210, is thinned.

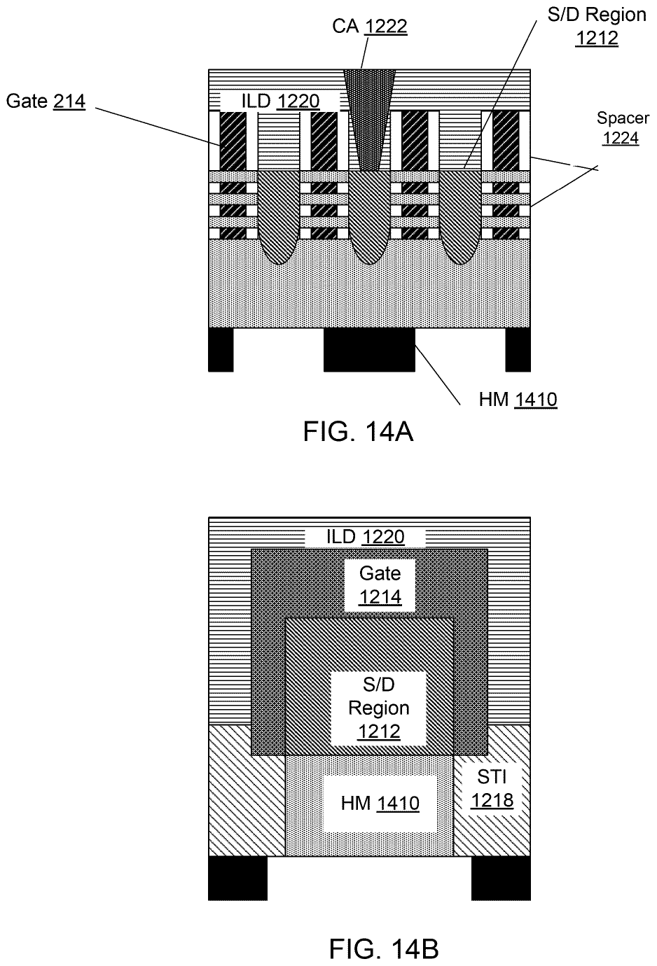

FIGS. 14A-14B, illustrate a semiconductor device during the formation of the backside contact, consistent with an illustrative embodiment. In some embodiments, the hard mask, HM 1410, is formed over the backside of the semiconductor device, followed by removal of portions of the HM 1410.

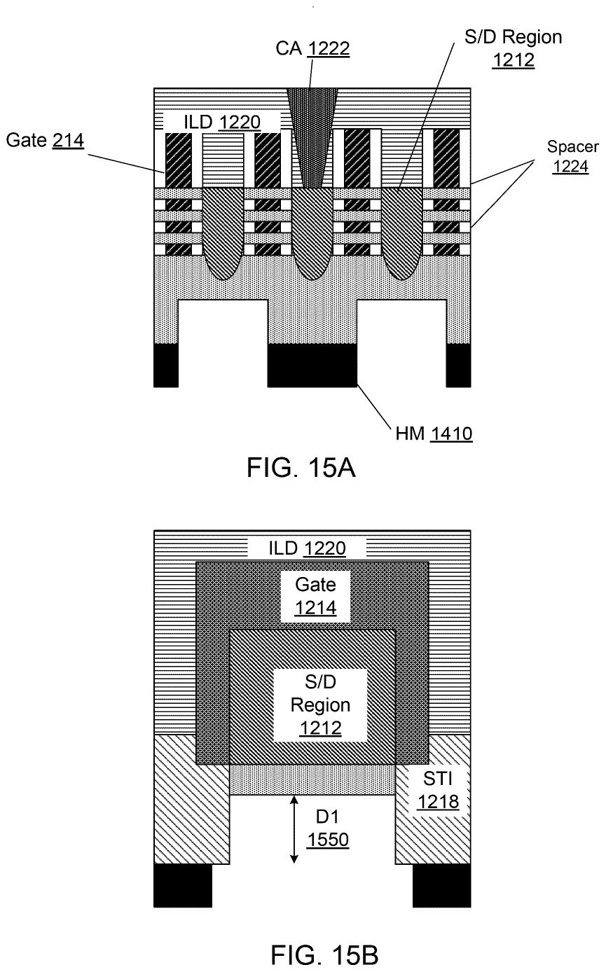

FIGS. 15A-15B, illustrate a semiconductor device after the etching of the first backside contact opening, consistent with an illustrative embodiment. In some embodiments, portions of the substrate between the HM 1410 are removed. The depth of the etched portion of the substrate can be d1 1550.

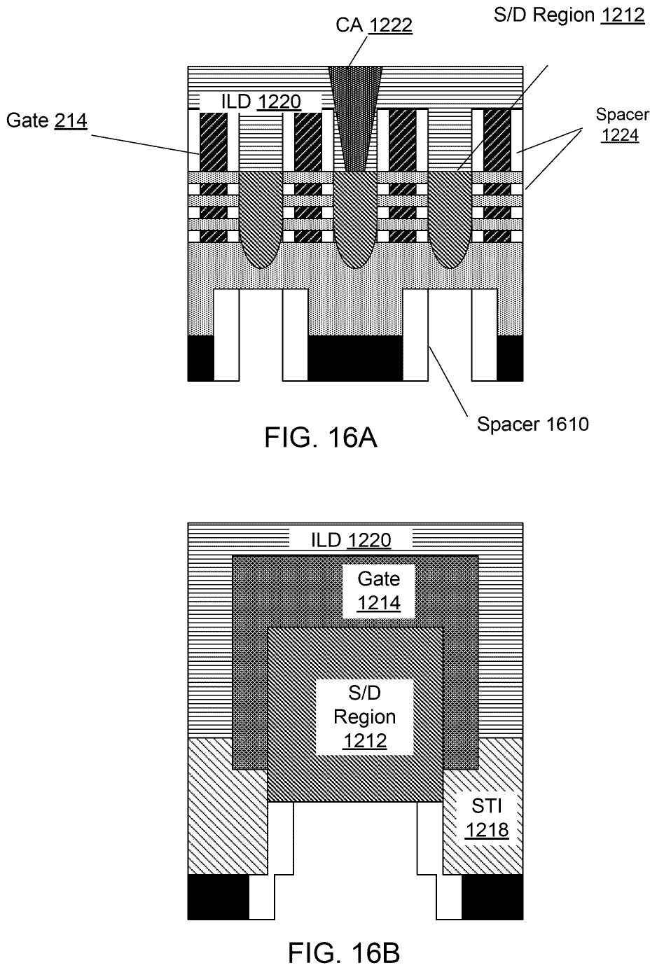

FIGS. 16A-16B illustrate a semiconductor device after the formation of a spacer, according to an embodiment. In some embodiments, a spacer 1610 is formed over the substrate and the HM 1410 on the backside of the semiconductor device.

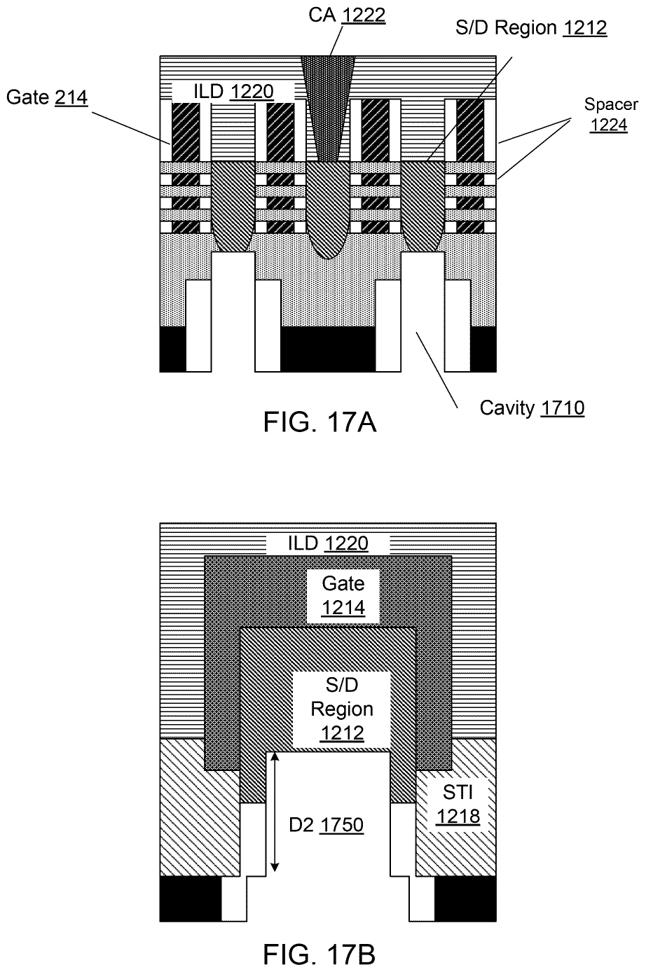

FIGS. 17A-17B, illustrate a semiconductor device after the etching of the second backside contact opening, consistent with an illustrative embodiment. In some embodiments, the portions of the source/drain regions that are exposed, are removed, such that a cavity 1710 with the height d2 1750, e.g., the height of the cavity inside the substrate, is formed.

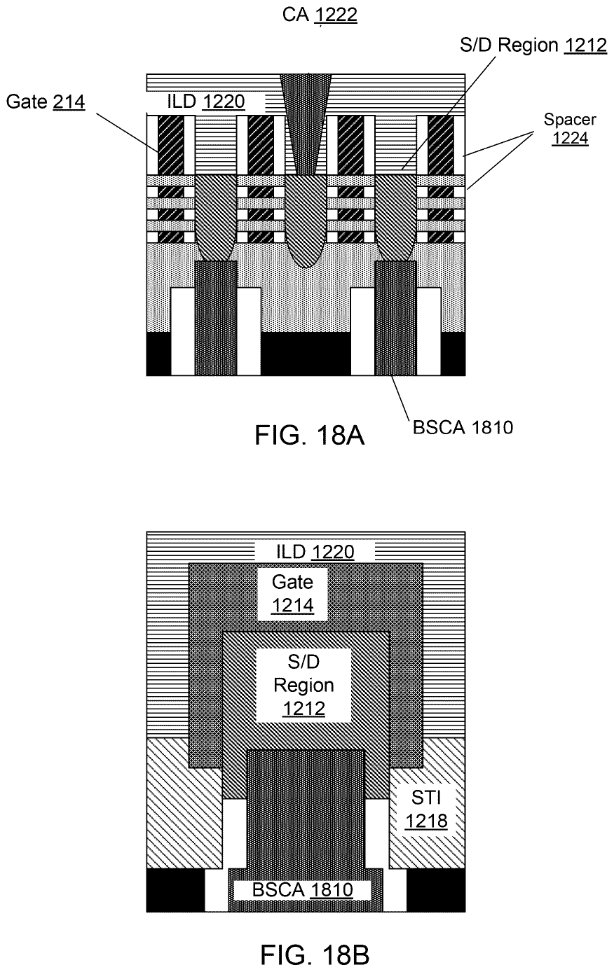

FIGS. 18A-18B, illustrate a semiconductor device after the formation of the backside contacts, consistent with an illustrative embodiment. In some embodiments, the cavity is filled with a suitable material to form the backside contact, BSCA 1810.

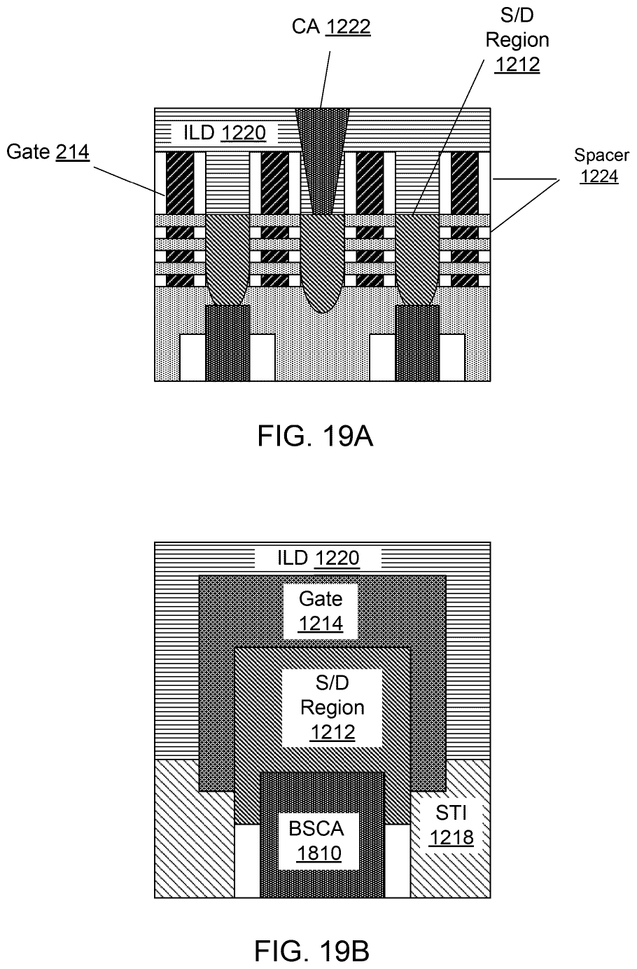

FIGS. 19A-19B, illustrate a semiconductor device after polishing the semiconductor device, consistent with an illustrative embodiment. In some embodiments, a chemical mechanical polishing, CMP, process is performed to remove the contaminants and thinning the backside of the semiconductor device including the HM.

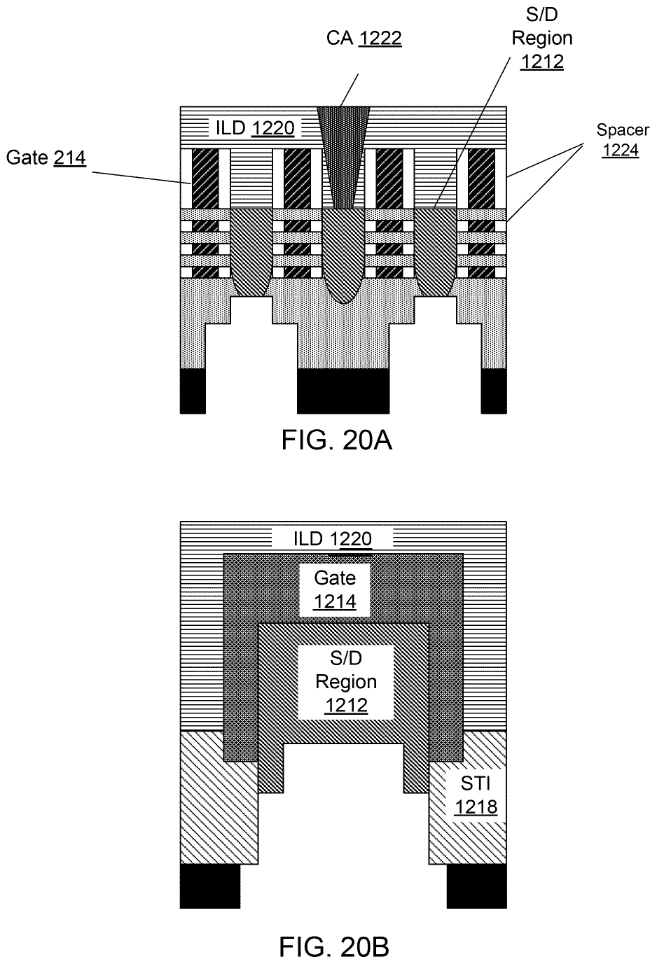

FIGS. 20A-20B, illustrate a semiconductor device after the removal of the spacer, consistent with an illustrative embodiment. In some embodiments, after the second backside contact opening is etched, the spacer is removed selectively from the backside of the semiconductor device.

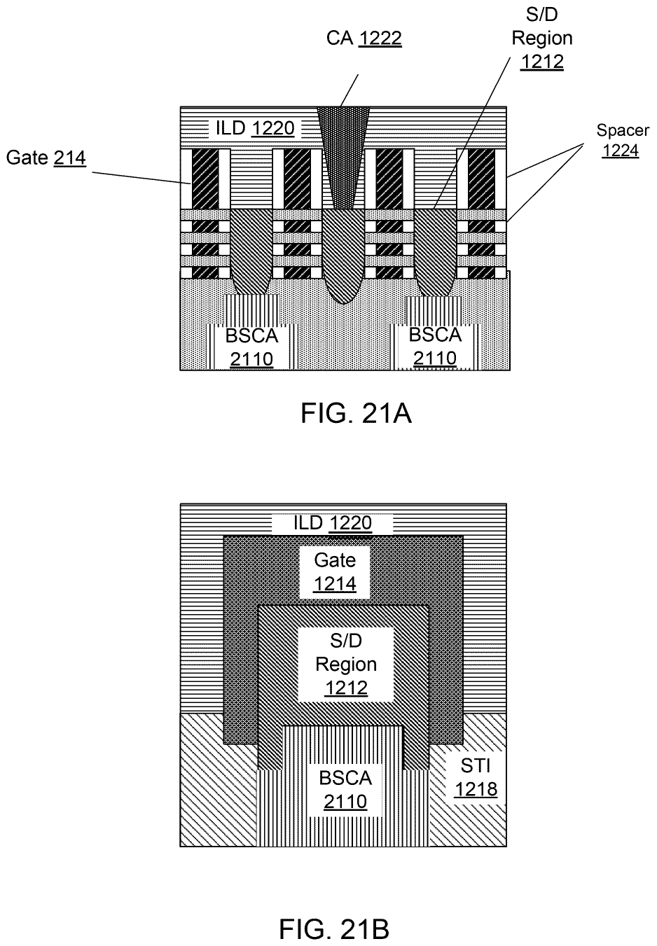

FIGS. 21A-21B, illustrate a semiconductor device after the formation of the backside contact, consistent with an illustrative embodiment. In some embodiments, the cavity and portions of the substrate that are exposed after the removal of the spacer are filled with a suitable material to form the backside contact, BSCA 2110.

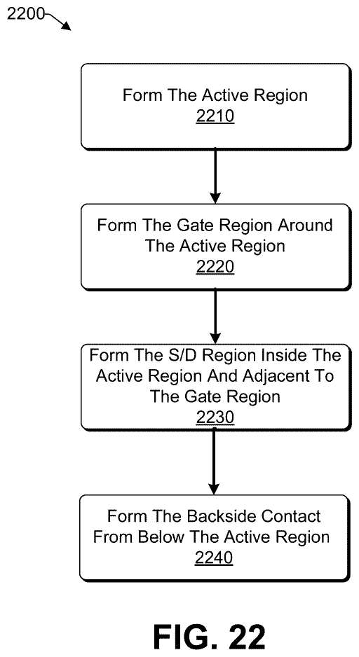

FIG. 22 illustrates a block diagram of a method 2200 for forming the semiconductor device, in accordance with some embodiments. As shown by block 2210, an active region is formed.

As shown by block 2220, a gate region around the active region is formed.

As shown by block 2230, at least one source/drain region inside the active region and adjacent to the gate region is formed.

As shown by block 2240, a backside contact from below the active region and having a first portion with a first height and a second portion with a second height is formed.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a gate region;
an active region surrounded by the gate region;
at least one source/drain region; and
a backside contact below the at least one source/drain region and having a first portion having a first height, wherein a length of the first portion along a width direction of the gate region is smaller than a length of the active region along the width direction of the gate region.

2. The semiconductor device of claim 1, further comprising a second portion, wherein the second portion is directly underneath the first portion, the second portion having a second height, wherein a length of the second portion along the width direction of the gate region is greater than the length of the first portion.

3. The semiconductor device of claim 2, wherein the second height is greater than the first height.

4. The semiconductor device of claim 1, further comprising offset spacers at two opposite edges of the length of the active region and outer edges of the backside contact.

5. The semiconductor device of claim 4, wherein the offset spacers are located on sidewalls of the backside contact and between the backside contact and a substrate.

6. The semiconductor device of claim 1, wherein a portion of the first portion of the backside contact extends vertically into the at least one source/drain region.

7. The semiconductor device of claim 1, wherein the at least one source/drain region is a first source/drain region, further comprising a frontside contact in conductive contact with a second source/drain region.

8. The semiconductor device of claim 2, wherein the first portion and the second portion comprise a same material.

9. The semiconductor device of claim 2, wherein the first portion and the second portion comprise different materials.

10. The semiconductor device of claim 2, wherein the first portion and the second portion comprise two or more materials.

11. A method of fabricating a semiconductor device, the method comprising:
forming an active region;
forming a gate region surrounded by the active region;
forming at least one source/drain region; and
forming a backside contact below the at least one source/drain region and having a first portion with a first height, wherein a length of the first portion along a width direction of the gate region is smaller than a length of the active region along the width direction of the gate region.

12. The method of claim 11, further comprising a second portion, wherein the second portion has a second height and is directly underneath the first portion, wherein a length of the second portion along the width direction of gate region is greater than the length of the first portion.

13. The method of claim 12, wherein the second height is greater than the first height.

14. The method of claim 11, further comprising forming an offset spacer which lines an inner periphery of an opening within which the backside contact is formed.

15. The method of claim 11, further comprising forming a portion of the first portion that vertically extends into the at least one source/drain region.

16. The method of claim 11, further comprising forming a frontside contact to a frontside of the semiconductor device.

17. The method of claim 12, wherein the first portion and the second portion comprise a same material.

18. The method of claim 12, wherein the first portion and the second portion comprise different materials.

19. A semiconductor device, comprising:
a source/drain region;
a backside contact below the source/drain region, wherein a length of the backside contact along an active region of the semiconductor device is smaller than a length of the active region; and
an offset spacer at two opposite edges of the source/drain region and outer edges of the backside contact.

20. The semiconductor device of claim 19, wherein the semiconductor device is a transistor and the active region is a channel region underneath a gate of the transistor, and the lengths of the backside contact and the active region are measured along a width direction of the gate, and wherein the offset spacer lines an inner periphery of at least a vertical portion of the backside contact, wherein at least a portion of the backside contact extends vertically into the source/drain region.
